(19) United States
(12) Patent Application Publication
(10) Pub. No.: US 2026/0204219 A1
(43) Pub. Date: Jul. 16, 2026

(54) SUB-PIXEL, DISPLAY DEVICE INCLUDING THE SUB-PIXEL, AND ELECTRONIC DEVICE

(71) Applicant: Samsung Display Co., LTD., Yongin-si (KR)

(72) Inventors: Sang Hyun HEO, Yongin-si (KR); Seung Ha BAEK, Yongin-si (KR); Oh Jo KWON, Yongin-si (KR); Tae Hun LEE, Yongin-si (KR)

(21) Appl. No.: 19/369,671

(22) Filed: Oct. 27, 2025

(30) Foreign Application Priority Data
Jan. 15, 2025 (KR) 10-2025-0006171

(51) Int. Cl. G09G 3/3233; G09G 3/3266

(52) U.S. Cl. CPC G09G 3/3233; G09G 3/3266; G09G 2300/0426; G09G 2300/0819; G09G 2300/0852; G09G 2300/0861; G09G 2310/08; G09G 2320/0233; G09G 2320/0238; G09G 2320/043; G09G 2330/021

(57) ABSTRACT

A sub-pixel includes a sub-pixel circuit, a light emitting device, and a first transistor. The sub-pixel circuit is connected to a first power voltage node to which a first power voltage is input, a data line, a first sub-gate line, and a first sub-emission control line. The light emitting device has a cathode electrode connected to a second power voltage node to which a second power voltage is input. The first transistor is connected between an anode electrode of the light emitting device and the sub-pixel circuit, turns off in response to a first voltage input to a second sub-emission control line to which a gate electrode of the first transistor is connected, and turns on in response to a second voltage input to the second sub-emission control line. A third voltage is input to the second sub-emission control line during an emission period.

This application claims priority to Korean Patent Application No. 10-2025-0006171, filed on January 15, 2025, and all the benefits accruing therefrom under 35 U.S.C. §119, the content of which in its entirety is herein incorporated by reference.

### BACKGROUND

### Field

Various embodiments of the present disclosure relate to a sub-pixel, a display device including the same, and an electronic device.

### Description of Related Art

As information technology has developed, the importance of a display device, which is a connection medium between a user and information, has been highlighted. Accordingly, the use of display devices such as, for example, a liquid crystal display device, an organic light emitting display device, and the like has been increasing.

In recent years, a sub-pixel capable of reducing power consumption and maintaining uniform luminance regardless of deterioration of a light emitting device has been desired.

### SUMMARY

Embodiments of the present disclosure provide a sub-pixel capable of maintaining approximately uniform luminance even while power consumption is reduced and a light emitting device deteriorates, a display device including the sub-pixel, and an electronic device.

A sub-pixel according to embodiments of the present disclosure includes a sub-pixel circuit, a light emitting device, and a first transistor. The sub-pixel circuit is connected to a first power voltage node to which a first power voltage is input, a data line, a first sub-gate line, and a first sub-emission control line. The light emitting device has a cathode electrode connected to a second power voltage node to which a second power voltage is input. The first transistor is connected between an anode electrode of the light emitting device and the sub-pixel circuit, turns off in response to a first voltage is input to a second sub-emission control line to which a gate electrode of the first transistor is connected, and turns on in response to a second voltage input to the second sub-emission control line. A third voltage having a voltage value different from the first voltage and the second voltage is input to the second sub-emission control line during an emission period in which a driving current is supplied from the sub-pixel circuit to the light emitting device.

According to an embodiment, the third voltage has a voltage value between the first voltage and the second voltage.

According to an embodiment, the sub-pixel further includes a second transistor connected between the anode electrode of the light emitting device and an initialization voltage node to which an initialization voltage is input, and having a gate electrode connected to a second sub-gate line.

According to an embodiment, the sub-pixel circuit includes a third transistor, a fourth transistor, a fifth transistor, a first capacitor, and a second capacitor. The third transistor has a first electrode connected to a first node, a second electrode connected to the first transistor, and a gate electrode connected to a second node. The fourth transistor is connected between the data line and the second node, and has a gate electrode connected to the first sub-gate line. The fifth transistor is connected between the first power voltage node and the first node and has a gate electrode connected to the first sub-emission control line. The first capacitor is connected between the first node and the second node. The second capacitor is connected between the first node and the first power voltage node.

According to an embodiment, the first transistor, the second transistor, the third transistor, the fourth transistor, and the fifth transistor each include a body electrode to which the first power voltage is input.

According to an embodiment, one horizontal period includes a first period, a second period, and a third period. The first transistor is turned off during the first period, turned on during the second period and the third period, and turned on based on the third voltage during the emission period after the third period, wherein the first transistor has a predetermined resistance value based on the third voltage during the emission period.

According to an embodiment, the second transistor is turned on during the first period to the third period, the fourth transistor is turned on during the first period and the third period, and the fifth transistor is turned on during the first period and is turned off during the second period and the third period.

According to an embodiment, a reference voltage of a constant voltage is input to the data line during the first period, and a data signal corresponding to a grayscale is input to the data line during the third period.

According to an embodiment, the sub-pixel circuit further includes a sixth transistor connected between the second node and a reference voltage line to which a reference voltage is input, wherein the sub-pixel circuit includes a gate electrode connected to a third sub-gate line, and a body electrode which receives the first power voltage.

According to an embodiment, the second transistor is turned on during the first period to the third period, the fourth transistor is turned on during the third period, the fifth transistor is turned on during the first period, and is turned off during the second period and the third period, and the sixth transistor is turned on during the first period.

According to an embodiment, a data signal corresponding to a grayscale is input to the data line during the third period.

A display device according to embodiments of the present disclosure includes sub-pixels, a gate driver, and a data driver. The sub-pixels are connected to data lines, gate lines, and emission control lines. The gate driver drives the gate lines and the emission control lines. The data driver drives the data lines. At least one of the sub-pixels includes a sub-pixel circuit, a light emitting device, and a first transistor. The sub-pixel circuit is connected to a first power voltage node to which a first power voltage is input, a data line which is one of the data lines, a first sub-gate line which is one of the gate lines, and a first sub-emission control line which is one of the emission control lines. The light emitting device has a cathode electrode connected to a second power voltage node to which a second power voltage is input. The first transistor is connected between an anode electrode of the light emitting device and the sub-pixel circuit, and has a gate electrode connected to a second sub-emission control line which is one of the emission control lines. The gate driver supplies a first voltage to the second sub-emission control line, wherein the first transistor turns off in response to the first voltage; a second voltage to the second sub-emission control line, wherein the first transistor turns on in response to the second voltage; and a third voltage having a voltage value different from the first voltage and the second voltage to the second sub-emission control line during an emission period in which a driving current is supplied from the sub-pixel to the light emitting device.

According to an embodiment, the third voltage has a voltage value between the first voltage and the second voltage.

According to an embodiment, the sub-pixel further includes a second transistor connected between the anode electrode of the light emitting device and an initialization voltage node to which an initialization voltage is input, and the second transistor includes a gate electrode connected to a second sub-gate line which is one of the gate lines.

According to an embodiment, the sub-pixel circuit includes a third transistor, a fourth transistor, a fifth transistor, a first capacitor, and a second capacitor. The third transistor has a first electrode connected to a first node, a second electrode connected to the first transistor, and a gate electrode connected to a second node. The fourth transistor is connected between the data line and the second node and has a gate electrode connected to the first sub-gate line. The fifth transistor is connected between the first power voltage node and the first node and has a gate electrode connected to the first sub-emission control line. The first capacitor is connected between the first node and the second node. The second capacitor is connected between the first node and the first power voltage node.

According to an embodiment, the gate driver supplies a disable second emission control signal of the first voltage to the second sub-emission control line during a first period; an enable second emission control signal of the second voltage to the second sub-emission control line during a second period and a third period; and a partial enable second emission control signal of the third voltage to the second sub-emission control line during the emission period after the third period.

According to an embodiment, the first period, the second period, and the third period are included in one horizontal period.

According to an embodiment, the gate driver supplies an enable first scan signal to the first sub-gate line such that the fourth transistor is turned on during the first period and the third period; an enable first emission control signal to the first sub-emission control line such that the fifth transistor is turned on during the first period, and a disable first emission control signal to the first sub-emission control line such that the fifth transistor is turned off during the second period and the third period; and an enable second scan signal to the second sub-gate line such that the second transistor is turned on during the first period to the third period.

According to an embodiment, the data driver supplies a reference voltage of a constant voltage during the first period, and a data signal corresponding to a grayscale during the third period.

According to an embodiment, the gate driver simultaneously supplies the enable first scan signal to a plurality of first sub-gate lines located on a plurality of horizontal lines during the first period.

According to an embodiment, one horizontal period includes the second period and the third period.

According to an embodiment, the sub-pixel circuit further includes a sixth transistor connected between the second node and a reference voltage line to which a reference voltage is input, and the sixth transistor includes a gate electrode connected to a third sub-gate line which is one of the gate lines.

According to an embodiment, the gate driver supplies an enable first scan signal to the first sub-gate line such that the fourth transistor is turned on during the third period; an enable first emission control signal to the first sub-emission control line such that the fifth transistor is turned on during the first period, and a disable first emission control signal to the first sub-emission control line such that the fifth transistor is turned off during the second period and the third period; an enable second scan signal to the second sub-gate line such that the second transistor is turned on during the first period to the third period; and an enable third scan signal to the third sub-gate line such that the sixth transistor is turned on during the first period.

According to an embodiment, the third sub-gate line is connected in common to the sub-pixels.

An electronic device according to embodiments of the present disclosure includes a processor, a display module, memory, and a power module. The display module displays an image according to an image data signal input from the processor. The memory stores data information for an operation of the processor. The power module generates power which drives the display module. The display module includes sub-pixels connected to data lines, gate lines, and emission control lines, a gate driver which drives the gate lines and the emission control lines, and a data driver which drives the data lines. At least one of the sub-pixels includes a sub-pixel circuit, a light emitting device, and a first transistor. The sub-pixel circuit is connected to a first power voltage node to which a first power voltage is input, a data line which is one of the data lines, a first sub-gate line which is one of the gate lines, and a first sub-emission control line which is one of the emission control lines. The light emitting device has a cathode electrode connected to a second power voltage node to which a second power voltage is input. The first transistor is connected between an anode electrode of the light emitting device and the sub-pixel circuit, and has a gate electrode connected to a second sub-emission control line which is one of the emission control lines. The gate driver supplies a first voltage to the second sub-emission control line, wherein the first transistor turns off in response to the first voltage; a second voltage to the second sub-emission control line, wherein the first transistor turns on in response to the second voltage; and a third voltage having a voltage value different from the first voltage and the second voltage to the second sub-emission control line during an emission period in which a driving current is supplied from the sub-pixel to the light emitting device.

The technical problems of the present disclosure are not limited to the technical problems as mentioned above, and other technical problems that are not mentioned will be apparent to those skilled in the art from the following descriptions.

### BRIEF DESCRIPTION OF THE DRAWINGS

FIG. 1 is a block diagram illustrating an embodiment of a display device.

FIG. 2 is a block diagram illustrating an embodiment of one of sub-pixels of FIG. 1.

FIG. 3 is a diagram illustrating an embodiment of a gate driver which drives the sub-pixel illustrated in FIG. 2.

FIG. 4 is a schematic diagram of an embodiment of an equivalent circuit of the sub-pixel illustrated in FIG. 2.

FIG. 5 is a waveform diagram illustrating an embodiment of a method of driving the sub-pixel illustrated in FIG. 4.

FIGS. 6A to 6D are diagrams illustrating an operation process of a sub-pixel corresponding to a driving waveform of FIG. 5.

FIG. 7 is a diagram illustrating the amount of voltage change in a second node corresponding to the amount of voltage change in a light emitting device during an emission period.

FIG. 8 is a diagram illustrating a luminance change rate corresponding to deterioration of a light emitting device.

FIG. 9 is a waveform diagram illustrating a method of driving sub-pixels according to an embodiment of the present disclosure.

FIG. 10 is a schematic diagram of an embodiment of an equivalent circuit of the sub-pixel illustrated in FIG. 2.

FIG. 11 is a waveform diagram illustrating an embodiment of a method of driving the sub-pixel illustrated in FIG. 10.

FIG. 12 is a waveform diagram illustrating a method of driving sub-pixels according to an embodiment of the present disclosure.

FIG. 13 is a plan view of an embodiment of a display panel of FIG. 1.

FIG. 14 is a plan view of another embodiment of one of pixels of FIG. 13.

FIG. 15 is a plan view of another embodiment of one of the pixels of FIG. 13.

FIG. 16 is a block diagram of an electronic device according to an embodiment.

FIG. 17 illustrates schematic diagrams of an electronic device according to various embodiments.

### DETAILED DESCRIPTION

Embodiments of the present disclosure will be described more fully hereinafter with reference to the accompanying drawings. Like reference numerals may refer to like elements throughout the accompanying drawings.

Some embodiments are described with reference to the accompanying drawings in relation to a functional block, unit, and/or module. Those skilled in the art will understand that such a block, unit, and/or module may be physically implemented by, for example, a logic circuit, an individual component, a microprocessor, a hardwired circuit, a memory element, a line connection, and other electronic circuits, and may be formed using a semiconductor-based manufacturing technique or other manufacturing techniques. The block, unit, and/or module implemented by a microprocessor or other similar hardware may be programmed and controlled using software to perform various functions discussed herein, and may optionally be driven by firmware and/or software. In some aspects, each block, unit, and/or module may be implemented by dedicated hardware, or a combination of dedicated hardware that performs some functions and a processor (for example, one or more programmed microprocessors and related circuits) that performs a function different from those of the dedicated hardware. In some aspects, in some embodiments, the block, unit, and/or module may be physically separated into two or more individual blocks, units, and/or modules without departing from the scope of the present disclosure. In some aspects, in some embodiments, the block, unit and/or module may be physically combined into more complex blocks, units, and/or modules without departing from the scope of the present disclosure.

The term “connection” between two components may mean that both of an electrical connection and a physical connection are used inclusively, but embodiments of the present disclosure are not limited thereto. For example, a “connection” with reference to a circuit diagram may mean an electrical connection, and a “connection” with reference to a cross-sectional view and a plan view may mean a physical connection.

It will be understood that the terms “first,” “second,” “third,” and the like are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel. The term “substantially constant” means approximately or actually constant.

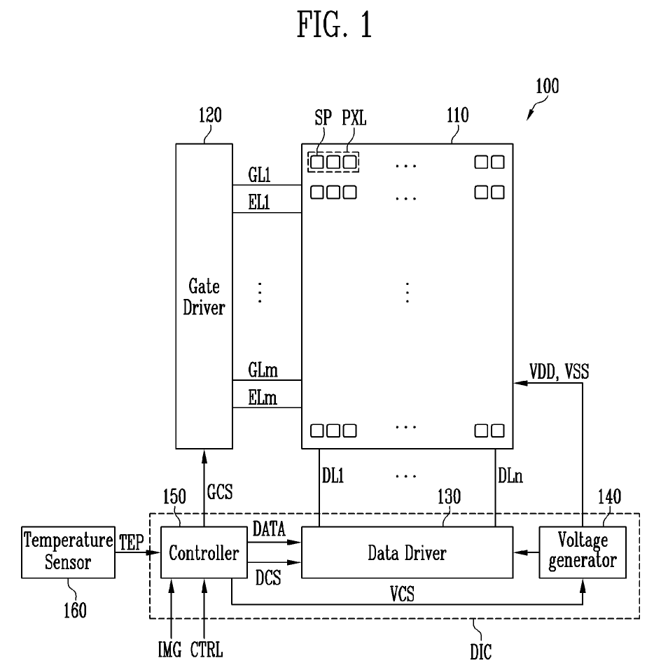

FIG. 1 is a block diagram illustrating an embodiment of a display device 100.

Referring to FIG. 1, the display device 100 may include a display panel 110, a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting device configured to generate light. Accordingly, each of the sub-pixels SP may generate light of a particular color, such as, for example, red, green, blue, cyan, magenta, yellow, or the like. Two or more sub-pixels of the sub-pixels SP may constitute one pixel PXL. For example, as illustrated in FIG. 1, three sub-pixels may constitute one pixel PXL.

The gate driver 120 is connected to the sub-pixels SP arranged in a row direction through the first to m-th gate lines GL1 to GLm. The gate driver 120 may output scan signals to the first to m-th gate lines GL1 to GLm in response to a gate control signal GCS. In embodiments, the gate control signal GCS may include a start signal indicating the start of each frame, a horizontal synchronization signal to output scan signals in synchronization with the timing at which data signals are applied, or the like.

In embodiments, first to m-th emission control lines EL1 to ELm connected to the sub-pixels SP in the row direction may be further provided. In this case, the gate driver 120 may include an emission driver configured to control the first to m-th emission control lines EL1 to ELm, and the emission driver may operate under the control of the controller 150.

The gate driver 120 may be located on one side of the display panel 110. However, embodiments are not limited thereto. For example, the gate driver 120 may be divided into two or more drivers that are physically and/or logically divided, and such drivers may be located on one side of the display panel 110 and the other side of the display panel 110 opposite to the one side. As such, the gate driver 120 may be located around the display panel 110 in various forms according to embodiments.

The data driver 130 is connected to the sub-pixels SP arranged in a column direction through the first to n-th data lines DL1 to DLn. The data driver 130 receives image data DATA and a data control signal DCS from the controller 150. The data driver 130 operates in response to the data control signal DCS. In embodiments, the data control signal DCS may include a source start pulse, a source shift clock, a source output enable signal, or the like.

The data driver 130 may use voltages from the voltage generator 140 to apply data signals having grayscale voltages corresponding to the image data DATA to the first to n-th data lines DL1 to DLn. In an example in which a scan signal is applied to each of the first to m-th gate lines GL1 to GLm, data signals corresponding to the image data DATA may be applied to the data lines DL1 to DLn. Corresponding sub-pixels SP may thus generate light corresponding to the data signals. Accordingly, an image is displayed on the display panel 110.

In embodiments, the gate driver 120 and the data driver 130 may include complementary metal-oxide semiconductor (CMOS) circuit devices.

The voltage generator 140 may operate in response to a voltage control signal VCS from the controller 150. The voltage generator 140 is configured to generate a plurality of voltages and provide the generated voltages to components of the display device 100. For example, the voltage generator 140 may be configured to generate a plurality of voltages by receiving an input voltage from outside the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level which is lower than the first power voltage VDD. In other embodiments, the first power voltage VDD or the second power voltage VSS may be provided by an external device of the display device 100.

In some aspects, the voltage generator 140 may generate various voltages. For example, the voltage generator 140 may generate an initialization voltage applied to the sub-pixels SP. For example, the voltage generator 140 may generate a reference voltage applied to the sub-pixels SP.

The controller 150 controls various operations of the display device 100. The controller 150 receives input image data IMG and a control signal CTRL for controlling the display of the input image data IMG from the outside. The controller 150 may provide the gate control signal GCS, the data control signal DCS, and the voltage control signal VCS in response to the control signal CTRL.

The controller 150 may convert the input image data IMG to be suitable for the display device 100 or the display panel 110 to output the image data DATA. In embodiments, the controller 150 may align the input image data IMG to be suitable for the sub-pixels SP in units of rows and output the image data DATA.

Two or more components of the data driver 130, the voltage generator 140, and the controller 150 may be mounted in one integrated circuit. As illustrated in FIG. 1, the data driver 130, the voltage generator 140, and the controller 150 may be included in a driver integrated circuit DIC. The data driver 130, the voltage generator 140, and the controller 150 may be functionally distinct components within one driver integrated circuit DIC. In other embodiments, at least one of the data driver 130, the voltage generator 140, and the controller 150 may be provided as a component separate from the driver integrated circuit DIC.

The display device 100 may include at least one temperature sensor 160. The temperature sensor 160 is configured to sense the temperature around the temperature sensor 160 and generate temperature data TEP indicative of the sensed temperature. In embodiments, the temperature sensor 160 may be located adjacent to the display panel 110 and/or the driver integrated circuit DIC.

The controller 150 may control various operations of the display device 100 in response to the temperature data TEP. In embodiments, the controller 150 may adjust luminance of an image output from the display panel 110 in response to the temperature data TEP. For example, the controller 150 may adjust the data signals and the first and second power voltages VDD and VSS by controlling components such as, for example, the data driver 130 and/or the voltage generator 140.

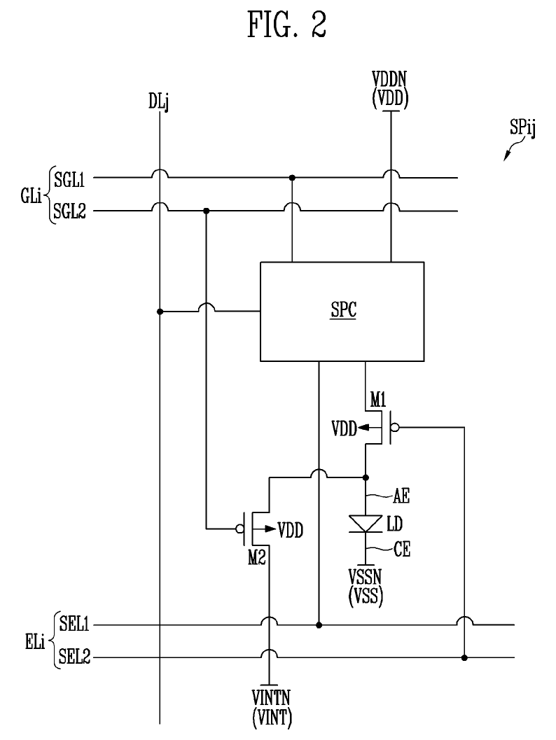

FIG. 2 is a block diagram illustrating an embodiment of one of the sub-pixels SP of FIG. 1. In FIG. 2, among the sub-pixels SP in FIG. 1, a sub-pixel SPij arranged in an i-th row (i is an integer greater than or equal to 1 and less than or equal to m) and a j-th column (j is an integer greater or equal to 1 and less than or equal to n) is illustrated as an example.

Referring to FIG. 2, the sub-pixel SPij may include a sub-pixel circuit SPC, a first transistor M1, a second transistor M2, and a light emitting device LD.

The light emitting device LD is connected between a first power voltage node VDDN and a second power voltage node VSSN. The first power voltage node VDDN is a node which provides the first power voltage VDD of FIG. 1, and the second power voltage node VSSN is a node which provides the second power voltage VSS of FIG. 1.

An anode electrode AE of the light emitting device LD is connected to the first power voltage node VDDN through the first transistor M1 and the sub-pixel circuit SPC, and a cathode electrode CE of the light emitting device LD may be connected to the second power voltage node VSSN. For example, the anode electrode AE of the light emitting device LD may be connected to the first power voltage node VDDN via the first transistor M1 and one or more transistors included in the sub-pixel circuit SPC.

The first transistor M1, the second transistor M2, and the sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The first transistor M1, the second transistor M2, and the sub-pixel circuit SPC are configured to control the light emitting device LD according to signals received through the above-described signal lines.

The i-th gate line GLi may include one or more sub-gate lines. In embodiments, as illustrated in FIG. 2, the i-th gate line GLi may include a first sub-gate line SGL1 and a second sub-gate line SGL2.

The i-th emission control line ELi may include one or more sub-emission control lines. In embodiments, as illustrated in FIG. 2, the i-th emission control line ELi may include a first sub-emission control line SEL1 and a second sub-emission control line SEL2.

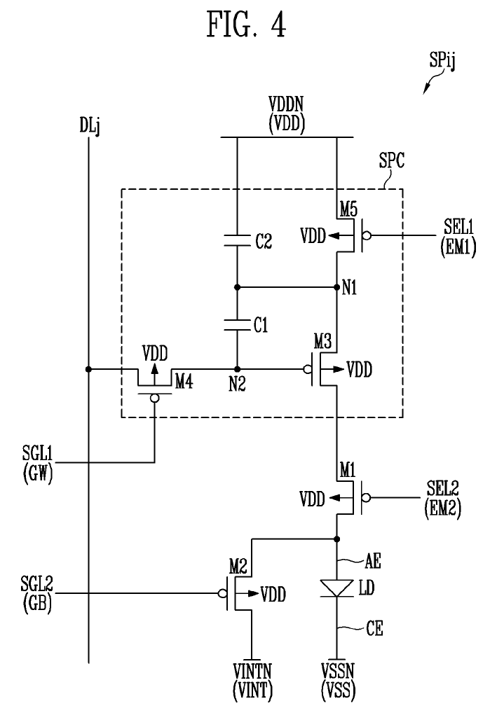

A first electrode of the first transistor M1 may be connected to the sub-pixel circuit SPC, and a second electrode may be connected to the anode electrode AE of the light emitting device LD. A gate electrode of the first transistor M1 may be electrically connected to the second sub-emission control line SEL2. The first transistor M1 may have a predetermined resistance value between the sub-pixel circuit SPC and the anode electrode AE of the light emitting device LD during an emission period in which the light emitting device LD emits light. A detailed description thereof will be provided below with reference to FIGS. 4 to 6D.

The second transistor M2 may be connected between the anode electrode AE of the light emitting device LD and an initialization voltage node VINTN. A gate electrode of the second transistor M2 may be electrically connected to the second sub-gate line SGL2. The second transistor M2 may be turn on in response to an enable second scan signal which is supplied to the second sub-gate line SGL2 and may electrically connect the anode electrode AE of the light emitting device LD and the initialization voltage node VINTN.

The initialization voltage node VINTN may be configured to transfer an initialization voltage VINT. The initialization voltage VINT may be provided by the voltage generator 140 illustrated in FIG. 1. The initialization voltage VINT may be set to a voltage at which the light emitting device LD turns off when supplied to the anode electrode AE of the light emitting device LD.

The sub-pixel circuit SPC may operate in response to a scan signal received through the first sub-gate line SGL1 and an emission control signal received through the first sub-emission control line SEL1.

The sub-pixel circuit SPC may receive a data signal through the j-th data line DLj. The sub-pixel circuit SPC may store a voltage corresponding to the data signal in response to the scan signal received through the first sub-gate line SGL1. In response to the emission control signal received through the first sub-emission control line SEL1, the sub-pixel circuit SPC may adjust the amount of driving current flowing from the first power voltage node VDDN to the second power voltage node VSSN through the light emitting device LD according to the stored voltage. Accordingly, the light emitting device LD may generate light of luminance corresponding to the data signal.

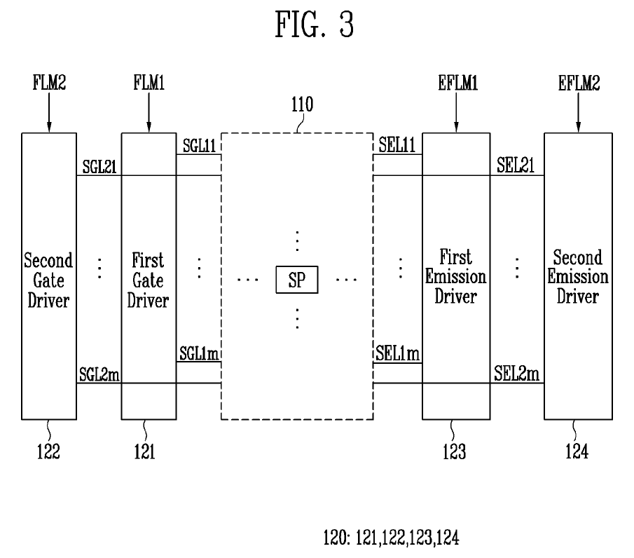

FIG. 3 is a diagram illustrating an embodiment of the gate driver 120 which drives the sub-pixel SPij illustrated in FIG. 2. The gate control signal GCS may include a first scan start signal FLM1, a second scan start signal FLM2, a first emission start signal EFLM1, and a second emission start signal EFLM2. In some aspects, the gate control signal GCS may include clock signals.

Referring to FIG. 3, the gate driver 120 may include a first gate driver 121, a second gate driver 122, a first emission driver 123, and a second emission driver 124. The drivers 121 to 124 are functionally separated, and at least two drivers may be integrated into one driver.

The first gate driver 121 may receive the first scan start signal FLM1 and generate a first scan signal while shifting the first scan start signal FLM1 in response to the clock signal. The first gate driver 121 may sequentially supply the first scan signal to first sub-gate lines SGL11 to SGL1m.

The second gate driver 122 may receive the second scan start signal FLM2 and generate a second scan signal while shifting the second scan start signal FLM2 in response to the clock signal. The second gate driver 122 may sequentially supply the second scan signal to second sub-gate lines SGL21 to SGL2m.

The first scan signal and the second scan signal may have a gate-on voltage such that a transistor included in the sub-pixels SP may be turned on. The first scan signal and the second scan signal which have the gate-on voltage may be referred to as an enable first scan signal and an enable second scan signal, respectively. For example, a logic low level voltage may be supplied to a P-type transistor as an enable scan signal, and a logic high level voltage may be provided to an N-type transistor as the enable scan signal. In an embodiment, the enable first scan signal and the enable second scan signal may be at a logic low level.

The terms “high level” (or alternatively, “high voltage level”) and “low level” (or alternatively, “low voltage level”) are relative terms describing levels of voltages which, when applied to a transistor described herein, may activate a transistor (e.g., turn “ON” the transistor) or deactivate a transistor (e.g., turn “OFF” the transistor) based on transistor type (e.g., P-type, N-type, or the like).

In some aspects, the gate drivers 121 and 122 may supply a disable scan signal during a period in which the enable scan signal is not supplied to the sub-gate lines SGL11 to SGL1m and SGL21 to SGL2m. The disable scan signal may have a gate-off voltage such that the transistor included in the sub-pixels SP may be turned off.

The terms “enable signal” (and similarly, “enable scan signal”, “enable control signal”, “enable emission control signal”, and the like) and “disable signal” (and similarly, “disable scan signal”, “disable control signal”, “disable emission control signal”, and the like) may refer to states in which the light emission control signal EM has a voltage which, when applied to a transistor described herein, activate the transistor (e.g., turn “ON” the transistor) or deactivate the transistor (e.g., turn “OFF” the transistor) based on transistor type (e.g., P-type, N-type, or the like).

The first sub-gate line SGL1 illustrated in FIG. 2 may be one of the first sub-gate lines SGL11 to SGL1m. The second sub-gate line SGL2 illustrated in FIG. 2 may be one of the second sub-gate lines SGL21 to SGL2m.

The first emission driver 123 may generate a first emission control signal while shifting the first emission start signal EFLM1 in response to the clock signal. The first emission driver 123 may sequentially supply the first emission control signal to first sub-emission control lines SEL11 to SEL1m.

The second emission driver 124 may generate a second emission control signal while shifting the second emission start signal EFLM2 in response to the clock signal. The second emission driver 124 may sequentially supply the second emission control signal to second sub-emission control lines SEL21 to SEL2m.

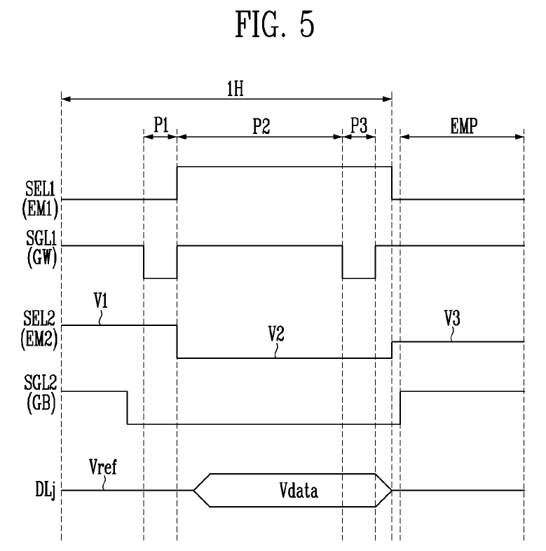

The first emission control signal and the second emission control signal may have a gate-off voltage such that the transistor included in the sub-pixels SP may be turned off. The first emission control signal and the second emission control signal which have the gate-off voltage may be referred to as a disable first emission control signal and a disable second emission control signal. The disable emission control signal may have a first voltage V1 corresponding to the gate-off voltage as illustrated in FIG. 5.

For example, a logic high level voltage may be supplied to a P-type transistor as a disable emission control signal, and a logic low level voltage may be provided to an N-type transistor as the disable emission control signal. In an embodiment, the disable emission control signal may be at a logic high level.

During a period in which the disable emission control signal is not supplied, the emission drivers 123 and 124 may supply the enable emission control signal to the sub-emission control lines SEL11 to SEL1m and SEL21 to SEL2m. The enable emission control signal may have a gate-on voltage such that the transistor included in the sub-pixels SP may be turned on. The enable emission control signal may have a second voltage V2 corresponding to the gate-on voltage as illustrated in FIG. 5.

The second emission driver 124 may supply a partial enable emission control signal during a period in which the enable second emission control signal and the disable second emission control signal are not supplied to the second sub-emission control lines SEL21 to SEL2m. The partial enable emission control signal may have a third voltage V3 between the first voltage V1 and the second voltage V2, as illustrated in FIG. 5. The transistor supplied with the third voltage V3 is not fully turned on, but may be turned on with a predetermined resistance value.

The first sub-emission control line SEL1 illustrated in FIG. 2 may be one of the first sub-emission control lines SEL11 to SEL1m. The second sub-emission control line SEL2 illustrated in FIG. 2 may be one of the second sub-emission control lines SEL21 to SEL2m.

FIG. 4 is a schematic diagram of an embodiment of an equivalent circuit of the sub-pixel SPij illustrated in FIG. 2.

Referring to FIG. 4, the sub-pixel SPij may include the sub-pixel circuit SPC, the first transistor M1, the second transistor M2, and the light emitting device LD.

The light emitting device LD may include the anode electrode AE, the cathode electrode CE and an emission layer. The emission layer may be arranged between the anode electrode AE and the cathode electrode CE. The anode electrode AE of the light emitting device LD is electrically connected to the first power voltage node VDDN via the first transistor M1, a third transistor M3, a first node N1, and a fifth transistor M5, and the cathode electrode CE of the light emitting device LD may be electrically connected to the second power voltage node VSSN. The light emitting device LD may generate light having luminance corresponding to the amount of driving current supplied from the first power voltage node VDDN to the second power voltage node VSSN via the sub-pixel circuit SPC and the first transistor M1.

The light emitting device LD may be selected as an organic light emitting diode. The light emitting device LD may also be selected as an inorganic light emitting diode, such as, for example, a micro light emitting diode (LED), or a quantum dot light emitting diode. In some aspects, the light emitting device LD may be a device including a combination of organic and inorganic materials. Although FIG. 4 illustrates that the sub-pixel SPij includes a single light emitting device LD, in another embodiment, the sub-pixel SPij may include a plurality of light emitting devices LD, and the plurality of light emitting devices LD may be connected in series, in parallel, or in series-parallel with each other.

The sub-pixel circuit SPC may include the third transistor M3, a fourth transistor M4, the fifth transistor M5, a first capacitor C1, and a second capacitor C2.

The first transistor M1 to the fifth transistor M5 may be metal-oxide-semiconductor field-effect transistors (MOSFETs) including body electrodes. In this case, the first transistor M1 to the fifth transistor M5 may be mounted in a narrow area, and thus the sub-pixel SPij may be applied to a high-resolution panel.

In an embodiment, the first transistor M1 to the fifth transistor M5 may be P-type transistors. The first power voltage VDD may be supplied to the body electrode of each of the first transistor M1 to the fifth transistor M5.

A first electrode of the third transistor M3 may be connected to the first node N1, and a second electrode may be connected to the first electrode of the first transistor M1. Here, “connected” includes the meaning of electrically connected. The first node N1 may be connected to the first power voltage node VDDN via the fifth transistor M5. A gate electrode of the third transistor M3 may be connected to a second node N2. The third transistor M3 may control the amount of driving current supplied from the first power voltage node VDDN to the second power voltage node VSSN via the light emitting device LD in response to a voltage of the second node N2.

The fourth transistor M4 may be connected between the data line DLj and the second node N2. A gate electrode of the fourth transistor M4 may be electrically connected to the first sub-gate line SGL1. The fourth transistor M4 as described herein may turn on in response to an enable first scan signal GW supplied to the first sub-gate line SGL1 and may electrically connect the data line DLj and the second node N2.

The fifth transistor M5 may be connected between the first power voltage node VDDN and the first node N1. A gate electrode of the fifth transistor M5 may be electrically connected to the first sub-emission control line SEL1. The fifth transistor M5 as described herein may turn off in response to a disable first emission control signal EM1 being input to the first sub-emission control line SEL1, and turn on in response to the enable first emission control signal EM1 being input. In an example in which the fifth transistor M5 is turned off, the first power voltage node VDDN and the first node N1 are electrically disconnected from each other, such that the light emitting device LD may be set to a non-emission state.

The first capacitor C1 may be connected between the first node N1 and the second node N2. The first capacitor C1 as described herein may store a voltage between the first node N1 and the second node N2.

The second capacitor C2 may be connected between the first node N1 and the first power voltage node VDDN. The second capacitor C2 as described herein may store a voltage between the first node N1 and the first power voltage node VDDN. The first capacitor C1 and the second capacitor C2 may store a data signal and a voltage corresponding to a threshold voltage of the third transistor M3.

FIG. 5 is a waveform diagram illustrating an embodiment of a method of driving the sub-pixel SPij illustrated in FIG. 4.

Referring to FIG. 5, one horizontal period 1H during which a data signal is supplied to the sub-pixel SPij may be divided into a first period P1, a second period P2, and a third period P3.

The data driver 130 may supply a data signal Vdata to the data line DLj during the third period P3. The data signal Vdata may have a predetermined voltage within a voltage range of the data signal corresponding to a grayscale. The period during which the data signal Vdata is supplied from the data driver 130 to the data line DLj may partially overlap with the second period P2.

The data driver 130 may supply a reference voltage Vref to the data line DLj during the first period P1. The reference voltage Vref may have a constant voltage. The period during which the reference voltage Vref is supplied from the data driver 130 to the data line DLj may partially overlap with the second period P2.

The gate driver 120 (or the first gate driver 121) may supply the enable first scan signal GW to the first sub-gate line SGL1 during the first period P1 and the third period P3. Then, based on the enable first scan signal GW, the fourth transistor M4 may be turned on during the first period P1 and the third period P3.

The gate driver 120 (or the second gate driver 122) may supply an enable second scan signal GB to the second sub-gate line SGL2 during the first period P1 to the third period P3. Then, based on the enable second scan signal GB, the second transistor M2 may be turned on during the first period P1 to the third period P3.

The gate driver 120 (or the first emission driver 123) may supply the enable first emission control signal EM1 to the first sub-emission control line SEL1 during the first period P1, and supply the disable first emission control signal EM1 to the first sub-emission control line SEL1 during the second period P2 and the third period P3. Then, the fifth transistor M5 may be turned on (i.e., based on the enable first emission control signal EM1) during the first period P1 and turned off (i.e., based on the disable first emission control signal EM1) during the second period P2 and the third period P3.

The gate driver 120 (or the second emission driver 124) may supply a disable second emission control signal EM2 having the first voltage V1 to the second sub-emission control line SEL2 during the first period P1. The first voltage V1 has a gate-off voltage, such that the first transistor M1 may be turned off during the first period P1.

The gate driver 120 (or the second emission driver 124) may supply the enable second emission control signal EM2 having the second voltage V2 to the second sub-emission control line SEL2 during the second period P2 and the third period P3. The second voltage V2 has a gate-on voltage, such that the first transistor M1 may be turned on during the second period P2 and the third period P3.

The second voltage V2 may be set such that the third transistor M3 is driven in a saturation region. The third transistor M3 may be driven in the saturation region when a source-drain voltage Vsd is set to a voltage higher than a voltage obtained by subtracting an absolute threshold voltage |Vth| from a source-gate voltage Vsg. For example, the second voltage V2 may be set such that the third transistor M3 is fully turned on.

The gate driver 120 (or the second emission driver 124) may supply a partial enable emission control signal having the third voltage V3 to the second sub-emission control line SEL2 during an emission period EMP. The third voltage V3 may have a voltage level which is lower than the first voltage V1 and a higher than the second voltage V2. The first transistor M1 supplied with the third voltage V3 may be turned on and have a predetermined resistance value during the emission period EMP.

The third voltage V3 may be set such that the amount of voltage change in the second node N2 due to the amount of voltage change in the anode electrode AE of the light emitting device LD is minimized or reduced. In an example in which the first transistor M1 is turned on and has a predetermined resistance value, the amount of voltage change in the second electrode (that is, a drain electrode) of the third transistor M3 may be minimized or reduced in response to the amount of voltage change in the anode electrode AE of the light emitting device LD. Then, the amount of voltage change in the second node N2 due to coupling of a parasitic capacitor (not illustrated) may be minimized or reduced based on the amount of voltage change in the second electrode of the third transistor M3, and thus the grayscale representation capability may be improved.

The third voltage V3 may have a voltage level which is higher than a voltage obtained by adding an operating point voltage of the light emitting device LD to the second power voltage VSS. The third voltage V3 may have a voltage level which is lower than a voltage obtained by subtracting an absolute threshold voltage of the first transistor M1 from the first voltage V1 (a gate turn-off voltage).

The first transistor M1 may be turned off during a period when the reference voltage Vref is supplied to the data line DLj, and the first transistor M1 may be turned on during a period when the data signal Vdata is supplied to the data line DLj. The first transistor M1 may be turned on and have a predetermined resistance value during the emission period EMP in which the light emitting device LD emits light.

The first period P1 may be an initialization period during which the anode electrode AE, the first node N1, and the second node N2 of the light emitting device LD are initialized.

The second period P2 may be a threshold voltage compensation period during which the threshold voltage of the third transistor M3 is compensated.

The third period P3 may be a writing period during which the voltage of the data signal is stored in the first capacitor C1 and the second capacitor C2.

The emission period EMP may be a period during which the light emitting device LD emits light corresponding to the voltage of the data signal.

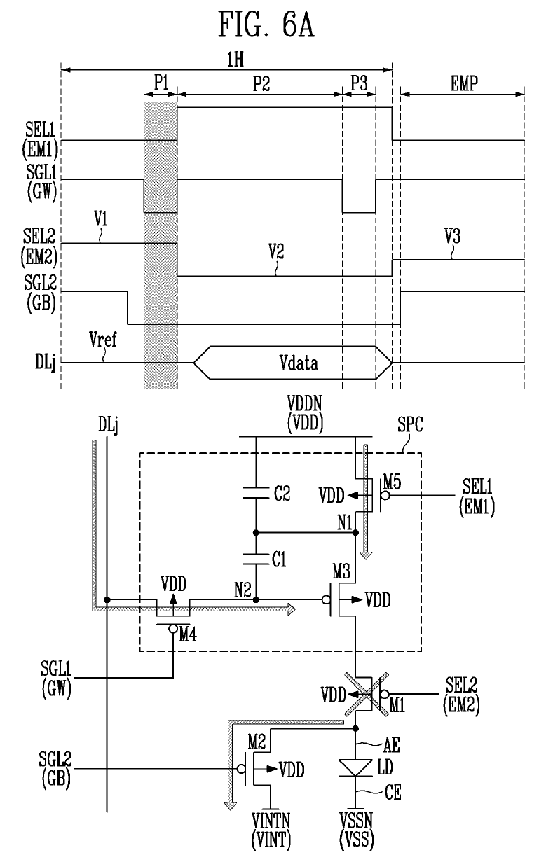

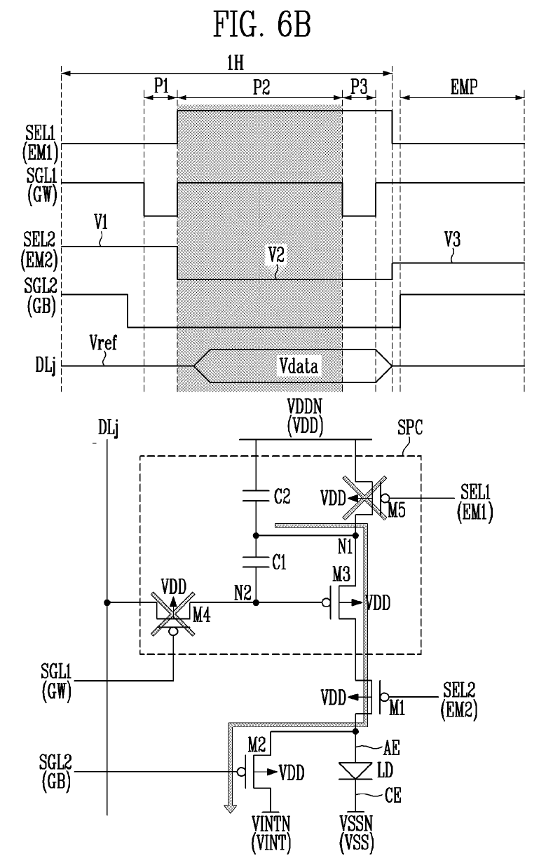

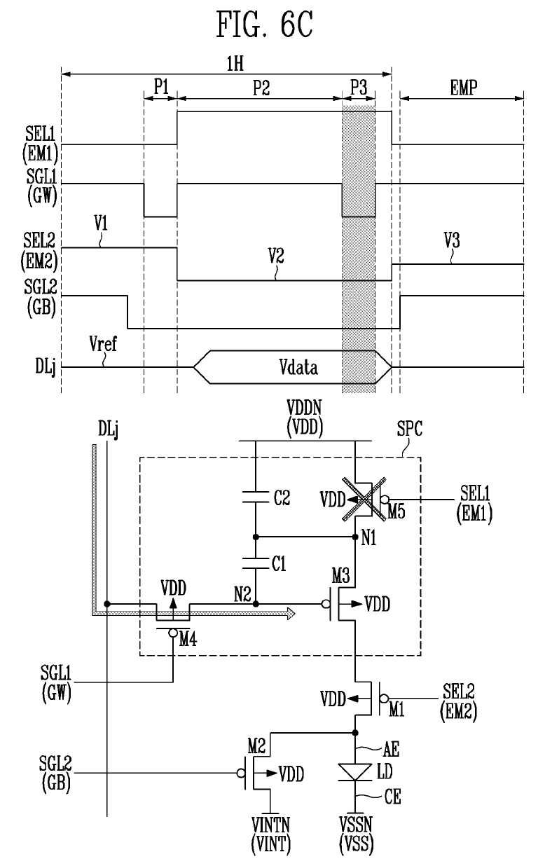

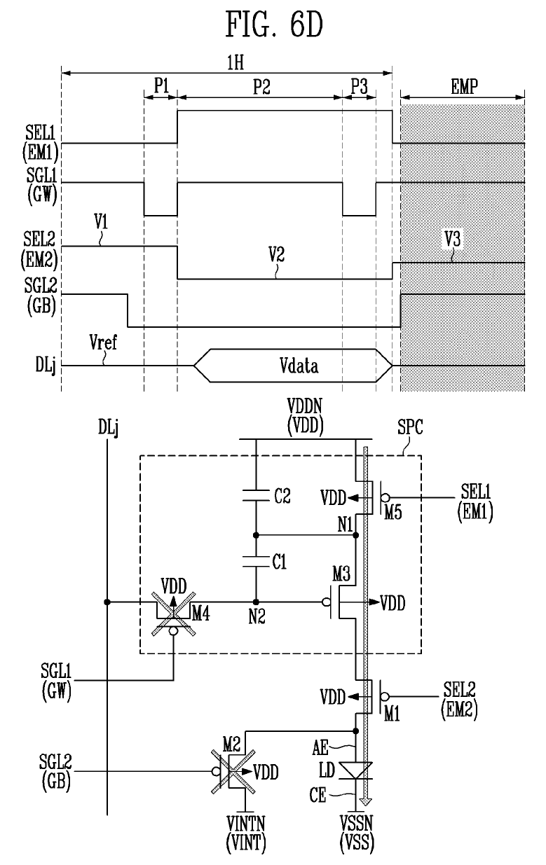

FIGS. 6A to 6D are diagrams illustrating an operation process of the sub-pixel SPij of FIG. 4 corresponding to a driving waveform of FIG. 5. FIGS. 6A to 6D further illustrate the driving waveform of FIG. 5, with the shaded areas highlighting periods of the driving waveform respective to the operation process of the sub-pixel SPij at FIGS. 6A to 6D.

Referring to FIG. 6A, during the first period P1, the enable first scan signal GW may be supplied to the first sub-gate line SGL1, the enable second scan signal GB may be supplied to the second sub-gate line SGL2, the enable first emission control signal EM1 may be supplied to the first sub-emission control line SEL1, and the disable second emission control signal EM2 may be supplied to the second sub-emission control line SEL2.

When the enable first scan signal GW is supplied to the first sub-gate line SGL1, the fourth transistor M4 may be turned on. In an example in which the fourth transistor M4 is turned on, the reference voltage Vref from the data line DLj is supplied to the second node N2, and the second node N2 may be initialized to the reference voltage Vref.

When the enable second scan signal GB is supplied to the second sub-gate line SGL2, the second transistor M2 may be turned on. In an example in which the second transistor M2 is turned on, the initialization voltage VINT from the initialization voltage node VINTN is supplied to the anode electrode AE of the light emitting device LD. In an example in which the initialization voltage VINT is supplied to the anode electrode AE of the light emitting device LD, the voltage remaining in the parasitic capacitor of the light emitting device LD may be discharged, and thus the black representation capability of the display device 100 may be improved. The initialization voltage VINT is set to a voltage at which the light emitting device LD does not emit light, such that the light emitting device LD may be set to a non-emission state during the first period P1.

When the enable first emission control signal EM1 is supplied to the first sub-emission control line SEL1, the fifth transistor M5 may be turned on. In an example in which the fifth transistor M5 is turned on, the first power voltage node VDDN and the first node N1 are electrically connected, such that the first node N1 may be initialized to the first power voltage VDD.

When the disable second emission control signal EM2 is supplied to the second sub-emission control line SEL2, the first transistor M1 may be turned off. In an example in which the first transistor M1 is turned off, the third transistor M3 and the anode electrode AE of the light emitting device LD may be electrically disconnected from each other. Therefore, the current supplied from the first power voltage node VDDN during the first period P1 is not supplied to the initialization voltage node VINTN, and thus power consumption may be reduced.

Referring to FIG. 6B, during the second period P2, the disable first scan signal GW may be supplied to the first sub-gate line SGL1, the enable second scan signal GB may be supplied to the second sub-gate line SGL2, the disable first emission control signal EM1 may be supplied to the first sub-emission control line SEL1, and the enable second emission control signal EM2 may be supplied to the second sub-emission control line SEL2.

When the disable first scan signal GW is supplied to the first sub-gate line SGL1, the fourth transistor M4 is turned off. In an example in which the fourth transistor M4 is turned off, the data line DLj and the second node N2 may be electrically disconnected from each other.

When the enable second scan signal GB is supplied to the second sub-gate line SGL2, the second transistor M2 may be maintained in the turned-on state, and thus the initialization voltage VINT may be supplied to the anode electrode AE of the light emitting device LD. During the second period P2, the light emitting device LD may be set to a non-emission state.

When the enable second emission control signal EM2 is supplied to the second sub-emission control line SEL2, the first transistor M1 may be turned on. In an example in which the first transistor M1 is turned on, the third transistor M3 and the anode electrode AE of the light emitting device LD may be electrically connected.

When the disable first emission control signal EM1 is supplied to the first sub-emission control line SEL1, the fifth transistor M5 may be turned off. In an example in which the fifth transistor M5 is turned off, the first power voltage node VDDN and the first node N1 may be electrically disconnected from each other. Accordingly, a current path from the first node N1 to the initialization voltage node VINTN via the third transistor M3, the first transistor M1, and the second transistor M2 may be formed.

During the second period P2, the second node N2 maintains the reference voltage Vref supplied during the first period P1, such that a voltage of the first node N1 may gradually decrease from the first power voltage VDD to a voltage obtained by adding the absolute threshold voltage of the first transistor M1 to the reference voltage Vref. In an example in which the voltage of the first node N1 is set to the voltage obtained by adding the absolute threshold voltage of the first transistor M1 to the reference voltage Vref, the third transistor M3 may be turned off. During the second period P2, a voltage corresponding to the threshold voltage of the third transistor M3 may be stored in the first capacitor C1.

Referring to FIG. 6C, during the third period P3, the enable first scan signal GW may be supplied to the first sub-gate line SGL1, the enable second scan signal GB may be supplied to the second sub-gate line SGL2, the disable first emission control signal EM1 may be supplied to the first sub-emission control line SEL1, and the enable second emission control signal EM2 may be supplied to the second sub-emission control line SEL2.

When the enable second scan signal GB is supplied to the second sub-gate line SGL2, the second transistor M2 may be maintained in the turned-on state, and thus the initialization voltage VINT may be supplied to the anode electrode AE of the light emitting device LD. During the third period P3, the light emitting device LD may be set to a non-emission state.

When the enable second emission control signal EM2 is supplied to the second sub-emission control line SEL2, the first transistor M1 may be turned on. In an example in which the first transistor M1 is turned on, the third transistor M3 and the anode electrode AE of the light emitting device LD may be electrically connected.

When the disable first emission control signal EM1 is supplied to the first sub-emission control line SEL1, the fifth transistor M5 may be turned off. In an example in which the fifth transistor M5 is turned off, the first power voltage node VDDN and the first node N1 may be electrically disconnected from each other.

When the enable first scan signal GW is supplied to the first sub-gate line SGL1, the fourth transistor M4 may be turned on. In an example in which the fourth transistor M4 is turned on, a voltage of the data signal Vdata from the data line DLj may be supplied to the second node N2. The voltage of the second node N2 is changed from the reference voltage Vref to the voltage of the data signal Vdata, and the voltage of the first node N1 may also be changed by the first capacitor C1.

For example, the voltage of the first node N1 may be changed corresponding to the amount of voltage change in the second node N2 and corresponding to the capacitance ratio of the first capacitor C1 and the second capacitor C2. The threshold voltage of the third transistor M3 and a voltage corresponding to the data signal Vdata may be stored in the first capacitor C1.

During the third period P3, a current may be supplied from the first node N1 to the initialization voltage node VINTN via the third transistor M3, the first transistor M1, and the second transistor M2, such that the voltage of the first node N1 may decrease. To prevent or mitigate the decrease in the voltage of the first node N1, in the embodiment, the third period P3 may be set shorter than the second period P2.

In an example in which the third period P3 is set to a relatively short duration, the voltage of the first node N1 may not decrease, or even when the voltage of the first node N1 decreases, the voltage of the first node N1 may decrease by a fine voltage (e.g., a reduced amount compared to the decrease in the voltage of the first node N1). The first capacitor C1 may maintain a voltage approximately corresponding to the threshold voltage of the third transistor M3 and a voltage corresponding to the data signal Vdata, and the sub-pixel SPij may generate light having luminance corresponding to a grayscale.

Referring to FIG. 6D, during the emission period EMP after the third period P3, the disable first scan signal GW may be supplied to the first sub-gate line SGL1, the disable second scan signal GB may be supplied to the second sub-gate line SGL2, the enable first emission control signal EM1 may be supplied to the first sub-emission control line SEL1, and the partial enable second emission control signal EM2 may be supplied to the second sub-emission control line SEL2.

When the disable first scan signal GW is supplied to the first sub-gate line SGL1, the fourth transistor M4 may be turned off. In an example in which the disable second scan signal GB is supplied to the second sub-gate line SGL2, the second transistor M2 may be turned off.

When the enable first emission control signal EM1 is supplied to the first sub-emission control line SEL1, the fifth transistor M5 may be turned on. In an example in which the fifth transistor M5 is turned on, the first power voltage node VDDN and the first node N1 may be electrically connected.

When the partial enable second emission control signal EM2 is supplied to the second sub-emission control line SEL2, the first transistor M1 may be turned on and have a predetermined resistance value. In an example in which the first transistor M1 is turned on, the third transistor M3 and the anode electrode AE of the light emitting device LD may be electrically connected. Then, a current path is formed during the emission period EMP through the first power voltage node VDDN, the fifth transistor M5, the first node N1, the third transistor M3, the first transistor M1, and the light emitting device LD to the second power voltage node VSSN. The third transistor M3 may control the amount of driving current supplied from the first power voltage node VDDN to the second power voltage node VSSN in response to the voltage of the second node N2. The light emitting device LD may generate light based on the amount of driving current.

When the amount of driving current is supplied to the light emitting device LD, a voltage of the anode electrode AE of the light emitting device LD may be changed. Because the first transistor M1 has a predetermined resistance value, the amount of voltage change in the second electrode of the first transistor M1 (and the second node N2), which is based on the amount of voltage change in the anode electrode AE of the light emitting device LD, may be minimized or reduced.

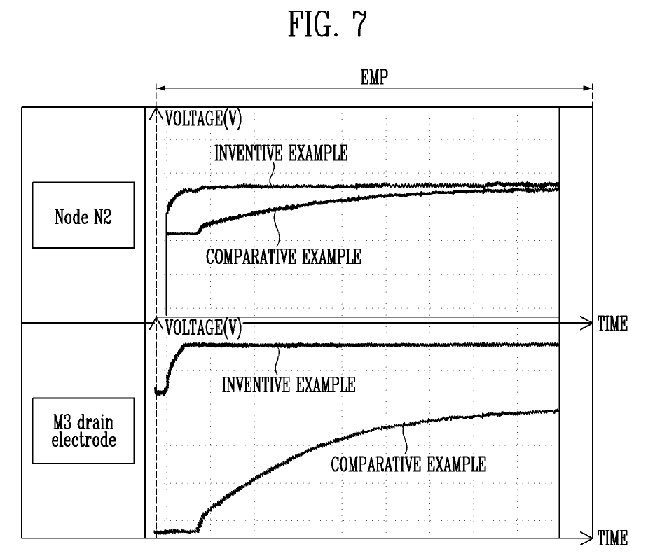

FIG. 7 is a diagram illustrating the amount of voltage change in the second node N2 corresponding to the amount of voltage change in the light emitting device LD during the emission period EMP. In FIG. 7, an inventive example may refer to the sub-pixel SPij of the embodiment illustrated in FIG. 4. In FIG. 7, a comparative example may refer to a case where the first transistor M1 is omitted from the sub-pixel SPij of the embodiment illustrated in FIG. 4.

Referring to FIG. 7, in the comparative example, the second electrode (that is, the drain electrode) of the third transistor M3 may be directly connected to the anode electrode AE of the light emitting device LD. The voltage of the anode electrode AE of the light emitting device LD may gradually increase during the emission period EMP by means of a parasitic capacitor. Then, the voltage of the second node N2 may be gradually changed by coupling of the parasitic capacitor between the gate electrode (that is, the second node N2) and the second electrode of the third transistor M3. In an example in which the voltage of the second node N2 is gradually changed during the emission period EMP, light of uniform luminance might not be generated in the sub-pixel SPij.

In the inventive example, the second electrode of the third transistor M3 and the anode electrode AE of the light emitting device LD may be electrically connected via the first transistor M1 having a predetermined resistance value. During the emission period EMP, a voltage of the second electrode of the third transistor M3 rapidly increases to a predetermined voltage, and the voltage of the second node N2 may also rapidly increase in response to the amount of voltage change in the second electrode of the third transistor M3. Then, the sub-pixel SPij of the inventive example may generate light of uniform luminance during the emission period EMP.

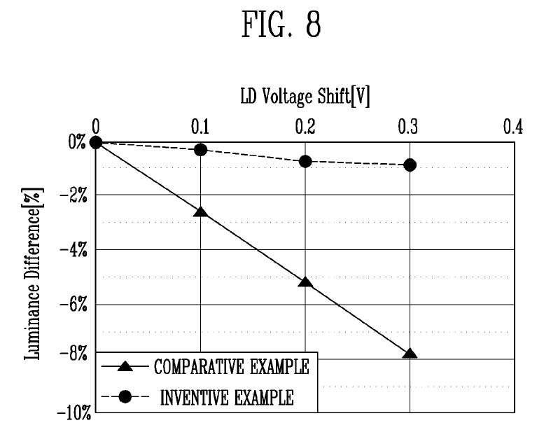

FIG. 8 is a diagram illustrating a luminance change rate corresponding to deterioration of the light emitting device LD. In FIG. 8, the X-axis represents a voltage shift of the light emitting device LD based on deterioration of the light emitting device LD, and the Y-axis represents a luminance change rate of the sub-pixel SPij.

Referring to FIG. 8, in the comparative example, when the voltage of the light emitting device LD is changed by 0.3 V, luminance of the sub-pixel SPij may decrease by approximately −8 %. That is, in the comparative example, the luminance of the sub-pixel SPij may rapidly decrease in response to the deterioration of the light emitting device LD.

In the inventive example, when the voltage of the light emitting device LD is changed by 0.3 V, the luminance of the sub-pixel SPij may decrease by approximately -1 % or less. In the inventive example, even when the light emitting device LD deteriorates, the sub-pixel SPij may maintain substantially constant luminance.

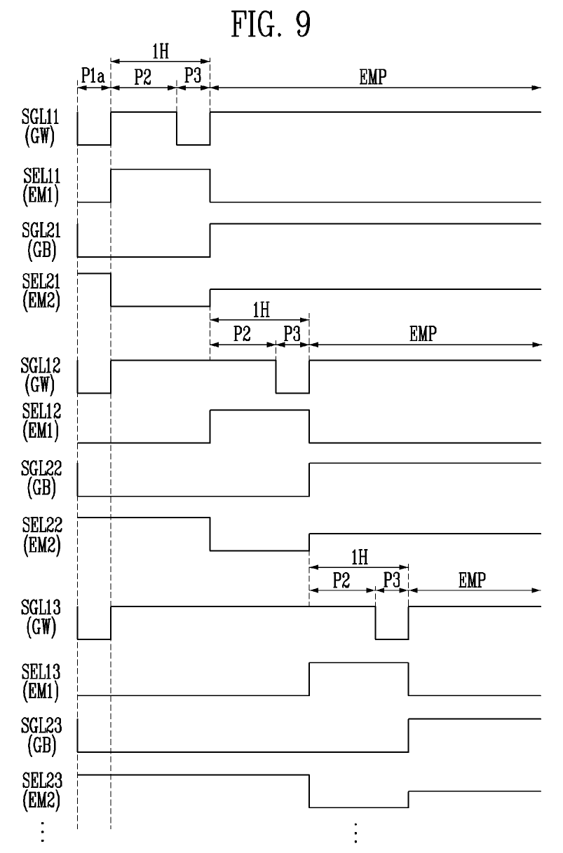

FIG. 9 is a waveform diagram illustrating a method of driving the sub-pixels SP according to an embodiment of the present disclosure. In descriptions with reference to FIG. 9, repetitive descriptions already mentioned above with reference to FIG. 5 will be omitted.

Referring to FIG. 9, during a first period P1a, the gate driver 120 (or the first gate driver 121) may simultaneously supply the enable first scan signal GW to a plurality of first sub-gate lines SGL11, SGL12, SGL13, …. For example, the display panel 110 may be divided in units of blocks to include at least two first sub-gate lines, and the sub-pixels SP included in the same block may be initialized simultaneously during the first period P1a. It is to be understood that descriptions herein using “…” may refer to additional instances of a component (e.g., first sub-gate lines, sub-emission control lines, and the like) not illustrated in a given FIGURE(e.g., FIG. 9).

During the first period P1a, the fourth transistor M4 included in each of the sub-pixels SP connected to the first sub-gate lines SGL11, SGL12, SGL13, … may be turned on. In an example in which the fourth transistor M4 is turned on, the reference voltage Vref may be supplied to the second node N2 of each of the sub-pixels SP connected to the first sub-gate lines SGL11, SGL12, SGL13, ….

To this end, the data driver 130 may supply the reference voltage Vref to the data lines DL1 to DLn during the first period P1a. During the first period P1a, the first power voltage VDD may be supplied to the first node N1 of the sub-pixels SP connected to the first sub-gate lines SGL11, SGL12, SGL13, … and the initialization voltage may be supplied to the anode electrode AE of the light emitting device LD.

During the first period P1a, the first transistor M1 included in each of the sub-pixels SP connected to the first sub-gate lines SGL11, SGL12, SGL13, … is turned off. Therefore, unnecessary current may be prevented or mitigated from flowing during the first period P1a.

When the sub-pixels SP located on a plurality of horizontal lines are simultaneously initialized during the first period P1a, only the second period P2 and the third period P3 may be included in each horizontal period 1H, and accordingly, more time may be allocated to threshold voltage compensation and the like of the third transistor M3.

After the sub-pixels SP located on the plurality of horizontal lines included in the same block are simultaneously initialized during the first period P1a, the sub-pixels SP included in the same block may emit light sequentially through the second period P2 and the third period P3 in units of horizontal lines.

In the above description, it is described that the sub-pixels SP are simultaneously initialized in units of blocks during the first period P1a, but embodiments are not limited thereto. For example, all sub-pixels SP included in the display panel 110 may be simultaneously initialized.

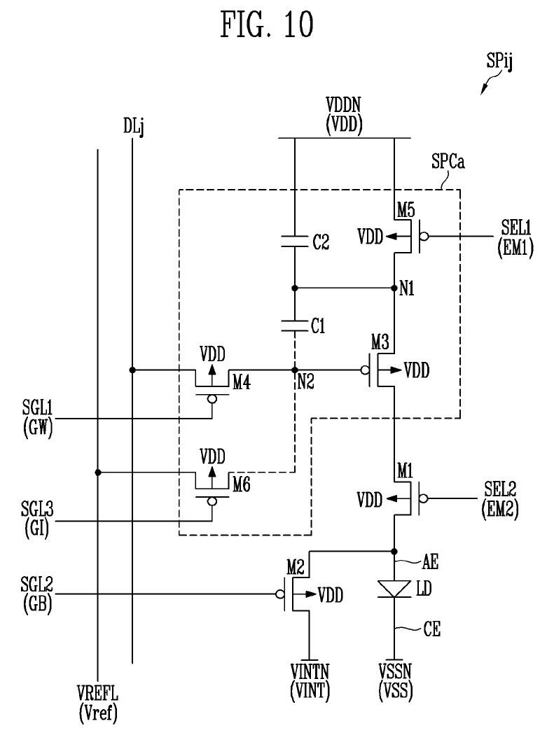

FIG. 10 is a schematic diagram of an embodiment of an equivalent circuit of the sub-pixel SPij illustrated in FIG. 2. In descriptions with reference to FIG. 10, the same reference numerals shall be assigned to the same elements as those in FIG. 4, and repetitive descriptions already mentioned above will be omitted.

Referring to FIG. 10, the sub-pixel SPij according to an embodiment may include a sub-pixel circuit SPCa, the first transistor M1, the second transistor M2, and the light emitting device LD.

The sub-pixel circuit SPCa may include the third transistor M3, the fourth transistor M4, the fifth transistor M5, a sixth transistor M6, the first capacitor C1, and the second capacitor C2.

The sixth transistor M6 may be connected to the second node N2 and a reference voltage line VREFL. A gate electrode of the sixth transistor M6 may be connected to a third sub-gate line SGL3. The sixth transistor M6 as described herein may turn on in response to an enable third scan signal GI which is input to the third sub-gate line SGL3 and may electrically connect the reference voltage line VREFL and the second node N2.

The sixth transistor M6 may be a metal-oxide-semiconductor field-effect transistor (MOSFET) including a body electrode. In an embodiment, the sixth transistor M6 may be a P-type transistor. The body electrode of the sixth transistor M6 may be supplied with the first power voltage VDD.

The third sub-gate line SGL3 is located on each horizontal line and may be connected to the sub-pixels SP arranged in the row direction. The third sub-gate line SGL3 may receive the enable third scan signal GI from the gate driver 120.

The reference voltage line VREFL may be connected in common to the sub-pixels SP. The reference voltage line VREFL may be supplied with the reference voltage Vref from the voltage generator 140 (or the data driver 130 or the controller 150).

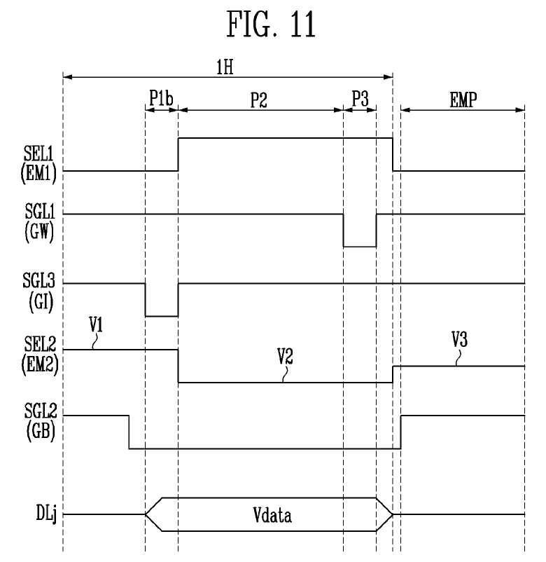

FIG. 11 is a waveform diagram illustrating an embodiment of a method of driving the sub-pixel SPij illustrated in FIG. 10. In descriptions with reference to FIG. 11, repetitive descriptions already mentioned above with reference to FIGS. 5 to 6D will be omitted.

Referring to FIG. 11, one horizontal period 1H during which a data signal is supplied to the sub-pixel SPij may include a first period P1b, the second period P2, and the third period P3.

The data driver 130 may supply the data signal Vdata to the data line DLj during the first period P1b to the third period P3. However, embodiments are not limited thereto, and the data driver 130 may supply the data signal Vdata for a duration which overlaps the third period P3.

The gate driver 120 may supply the disable first scan signal GW to the first sub-gate line SGL1 during the first period P1b. Therefore, the fourth transistor M4 may be turned off during the first period P1b.

The gate driver 120 may supply the enable third scan signal GI to the third sub-gate line SGL3 during the first period P1b. The sixth transistor M6 may turn on in response to the enable third scan signal GI being supplied to the third sub-gate line SGL3.

When the sixth transistor M6 is turned on, the reference voltage Vref from the reference voltage line VREFL is supplied to the second node N2, and the second node N2 may be initialized to the reference voltage VRef.

The sub-pixel SPij in FIG. 10 described herein is different from the sub-pixel SPij in FIG. 4 in that the sub-pixel SPij in FIG. 10 supplies the reference voltage Vref by using the sixth transistor M6 during the first period P1b, and other configurations and operations may be substantially the same as those of the sub-pixel SPij in FIG. 4.

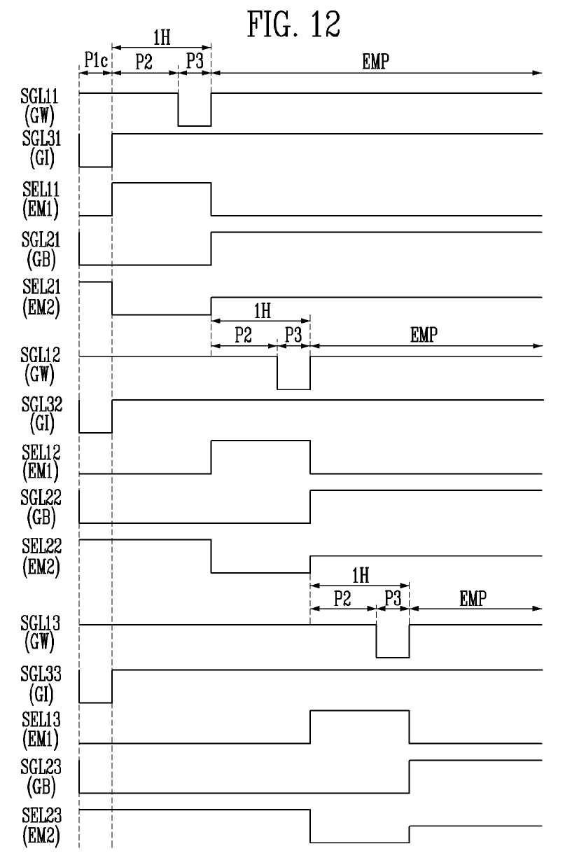

FIG. 12 is a waveform diagram illustrating a method of driving the sub-pixels SP according to an embodiment of the present disclosure.

Referring to FIG. 12, during a first period P1c, the gate driver 120 may supply the enable third scan signal GI to a plurality of third sub-gate lines SGL31, SGL32, SGL33, …, simultaneously. For example, the display panel 110 may be divided in units of blocks to include at least two third sub-gate lines, and the sub-pixels SP included in the same block may be initialized simultaneously during the first period P1c.

During the first period P1c, the sixth transistor M6 included in each of the sub-pixels SP connected to the third sub-gate lines SGL31, SGL32, SGL33, … may be turned on. In an example in which the sixth transistor M6 is turned on, the reference voltage Vref may be supplied to the second node N2 of each of the sub-pixels SP connected to the third sub-gate lines SGL31, SGL32, SGL33, …. In some aspects, the first power voltage VDD may be supplied to the first node N1 of the sub-pixels SP connected to the third sub-gate lines SGL31, SGL32, SGL33, … and the initialization voltage may be supplied to the anode electrode AE of the light emitting device LD during the first period P1c.

During the first period P1c, the first transistor M1 included in each of the sub-pixels SP connected to the third sub-gate lines SGL31, SGL32, SGL33, … is turned off. Therefore, unnecessary current may be prevented or mitigated from flowing during the first period P1c.

When the sub-pixels SP located on the plurality of horizontal lines are simultaneously initialized during the first period P1c, only the second period P2 and the third period P3 may be included in each horizontal period 1H, and thus more time may be allocated to threshold voltage compensation and the like of the third transistor M3.

After the sub-pixels SP located on the plurality of horizontal lines are initialized during the first period P1c, the sub-pixels SP may emit light sequentially through the second period P2 and the third period P3 in units of horizontal lines.

In the above description, it is described that the sub-pixels SP are simultaneously initialized in units of blocks during the first period P1c, but embodiments are not limited thereto. For example, all sub-pixels SP included in the display panel 110 may be simultaneously initialized.

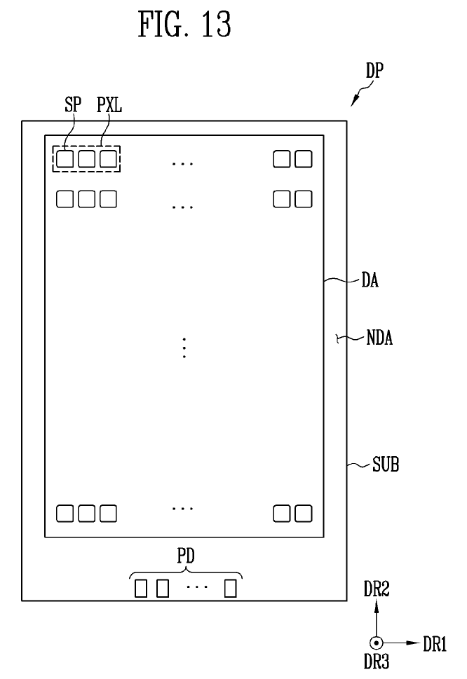

FIG. 13 is a plan view of an embodiment of the display panel 110 of FIG. 1.

Referring to FIG. 13, an embodiment DP of the display panel 110 of FIG. 1 may include a display area DA and a non-display area NDA. The display panel DP displays an image through the display area DA. The non-display area NDA is arranged around the display area DA.

The display panel DP may include a substrate SUB, the sub-pixels SP, and pads PD.

When the display panel DP is used as a display screen of a Head-Mounted Display (HMD) device, a Virtual Reality (VR) device, a Mixed Reality (MR) device, an Augmented Reality (AR) device, or the like, the display panel DP may be located very close to the user’s eyes. In this case, implementing the sub-pixels SP with a relatively high degree of integration may be desired. To increase the degree of integration of the sub-pixels SP, the substrate SUB may be provided as a silicon substrate. The sub-pixels SP and/or the display panel DP may be formed on the substrate SUB which is a silicon substrate. The display device 100 (see FIG. 1) including the display panel DP formed on the substrate SUB which is a silicon substrate may be referred to as an OLED on Silicon (OLEDoS) display device.

The sub-pixels SP are arranged in the display area DA on the substrate SUB. The sub-pixels SP may be arranged in a matrix form in a first direction DR1 and a second direction DR2 intersecting the first direction DR1. However, embodiments are not limited thereto. For example, the sub-pixels SP may be arranged in a zigzag shape in the first direction DR1 and the second direction DR2. For example, the sub-pixels SP may be arranged in the form of PENTILE^{TM}. The first direction DR1 may be a row direction and the second direction DR2 may be a column direction.

Two or more sub-pixels of the plurality of sub-pixels SP may constitute one pixel PXL.

In the non-display area NDA on the substrate SUB, a component for controlling the sub-pixels SP may be arranged. For example, wirings connected to the sub-pixels SP, such as, for example, the first to m-th gate lines GL1 to GLm and the first to n-th data lines DL1 to DLn of FIG. 1 may be disposed in the non-display area NDA.

At least one of the gate driver 120, the data driver 130, the voltage generator 140, the controller 150, and the temperature sensor 160 of FIG. 1 may be integrated in the non-display area NDA of the display panel DP. In embodiments, the gate driver 120 of FIG. 1 may be mounted to the display panel DP and arranged in the non-display area NDA. In other embodiments, the gate driver 120 may be implemented as an integrated circuit separate from the display panel DP. In embodiments, the temperature sensor 160 may be arranged in the non-display area NDA to sense the temperature of the display panel DP.

The pads PD are arranged in the non-display area NDA on the substrate SUB. The pads PD may be electrically connected to the sub-pixels SP through wirings. For example, the pads PD may be connected to the sub-pixels SP through the first to n-th data lines DL1 to DLn.

The pads PD may cause the display panel DP to interface with other components of the display device 100 (see FIG. 1). In embodiments, voltages and signals supportive of operations of components included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the voltage generator 140 through the pads PD. In an example in which the gate driver 120 is mounted on the display panel DP, the gate control signal GCS may be transmitted from the driver integrated circuit DIC to the gate driver 120 through the pads PD.

In embodiments, a circuit board may be electrically connected to the pads PD using a conductive adhesive such as, for example, an anisotropic conductive film. The circuit board may be a flexible printed circuit board (FPCB) or a flexible film having a flexible material. The driver integrated circuit DIC may be mounted to the circuit board and electrically connected to the pads PD.

In embodiments, the display area DA may have various shapes. The display area DA may have the shape of a closed loop including straight and/or curved sides. For example, the display area DA may have shapes such as, for example, a polygon, a circle, a semicircle, an ellipse, or the like.

In embodiments, the display panel DP may have a flat display surface. In other embodiments, the display panel DP may have an at least partially round display surface. In embodiments, the display panel DP may be bendable, foldable, or rollable. The display panel DP and/or the substrate SUB may include materials having flexible properties.

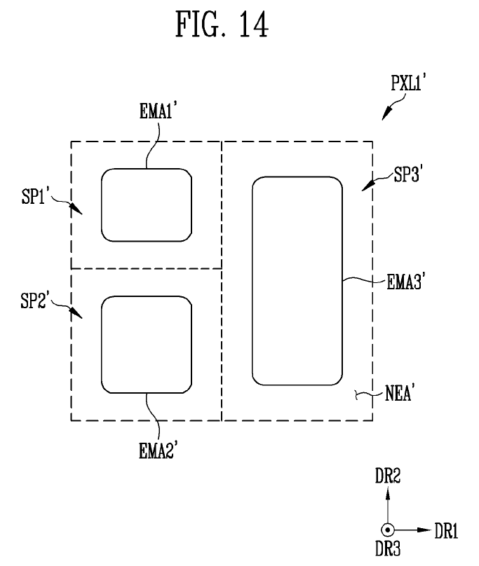

FIG. 14 is a plan view of another embodiment of one of pixels of FIG. 13.

Referring to FIG. 14, a first pixel PXL1’ may include first to third sub-pixels SP1’ to SP3’.

The first sub-pixel SP1’ may include a first emission area EMA1’ and a non-emission area NEA’ around the first emission area EMA1′. The second sub-pixel SP2’ may include a second emission area EMA2’ and the non-emission area NEA’ around the second emission area EMA2’. The third sub-pixel SP3’ may include a third emission area EMA3’ and the non-emission area NEA’ around the third emission area EMA3’.

The first sub-pixel SP1’ and the second sub-pixel SP2’ may be arranged in the second direction DR2. The third sub-pixel SP3’ may be arranged in the first direction DR1 with respect to each of the first and second sub-pixels SP1’ and SP2’.

The second sub-pixel SP2’ may have a greater area than the first sub-pixel SP1’, and the third sub-pixel SP3’ may have a greater area than the second sub-pixel SP2’. Accordingly, the second emission area EMA2’ may have a greater area than the first emission area EMA1’, and the third emission area EMA3’ may have a greater area than the second emission area EMA2’. However, embodiments are not limited thereto. For example, the first and second sub-pixels SP1’ and SP2’ may have substantially the same area as each other, and the third sub-pixel SP3’ may have a greater area than each of the first and second sub-pixels SP1’ and SP2’. As described herein, the areas of the first to third sub-pixels SP1’ to SP3’ may be variously changed according to embodiments.

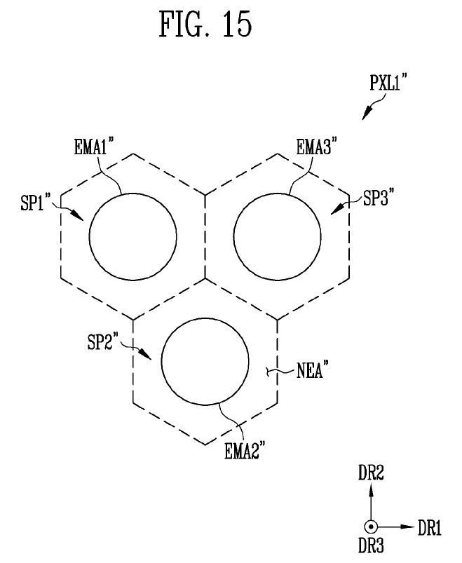

FIG. 15 is a plan view of another embodiment of one PXL1’’ of the pixels PXL of FIG. 13.

Referring to FIG. 15, a first sub-pixel SP1’’ may include a first emission area EMA1’’ and a non-emission area NEA’’ around the first emission area EMA1’’. A second sub-pixel SP2’’ may include a second emission area EMA2’’ and the non-emission area NEA’’ around the second emission area EMA2’’. A third sub-pixel SP3’’ may include a third emission area EMA3’’ and the non-emission area NEA’’ around the third emission area EMA3’’.

The first to third sub-pixels SP1’’ to SP3’’ may have polygonal shapes when viewed in the third direction DR3. For example, the shapes of the first to third sub-pixels SP1’’ to SP3’’ may be hexagons as illustrated in FIG. 15.

The first to third emission areas EMA1’’ to EMA3’’ may have circular shapes when viewed in the third direction DR3. However, embodiments are not limited thereto. For example, each of the first to third emission areas EMA1’’ to EMA3’’ may have a polygonal shape.

The first and third sub-pixels SP1’’, SP3’’ may be arranged in the first direction DR1. The second sub-pixel SP2’’ may be arranged with respect to the first sub-pixel SP1’’ in a direction (or diagonal direction) inclined by an acute angle with respect to the second direction DR2.

The arrangement of the sub-pixels is illustrative, and embodiments are not limited thereto. Each pixel includes two or more sub-pixels, which may be arranged in various ways, each of the sub-pixels may have various shapes, and an emission area of each of the sub-pixels may also have various shapes.

The display device 100 according to an embodiment may be applied to various electronic devices. An electronic device according to an embodiment includes the display device 100 described herein, and the electronic device may further include a module or device having an additional function other than the display device 100.

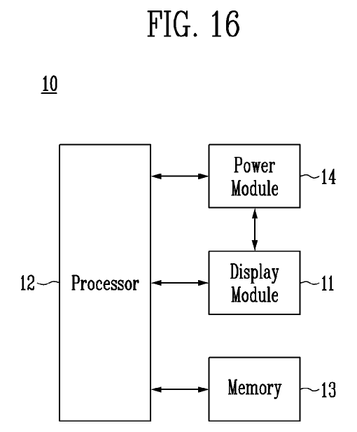

FIG. 16 is a block diagram of an electronic device 10 according to an embodiment. Referring to FIG. 16, the electronic device 10 according to an embodiment may include a display module 11, a processor 12, memory 13, and a power module 14.

The processor 12 may include at least one of a central processing unit (CPU), an application processor (AP), a graphics processing unit (GPU), a communication processor (CP), an image signal processor (ISP), and a controller.

The memory 13 may store data information supportive of an operation of the processor 12 or the display module 11. In an example in which the processor 12 executes the application stored in the memory 13, an image data signal and/or an input control signal are transferred to the display module 11, and the display module 11 may process the received signal and output image information through a display screen.

The power module 14 may include a power supply module such as, for example, a power adapter or a battery device, and a power conversion module which converts power supplied by the power supply module to generate power supportive of an operation of the electronic device 10.

At least one of the above-described components of the electronic device 10 may be included in the display device 100 according to the above-described embodiments. In some aspects, one or more of individual modules which are functionally included in one module may be included in the display device 100, and individual modules other than the one or more of the individual modules may be provided separately from the display device 100. For example, the display device 100 may include the display module 11, and the processor 12, the memory 13, and the power module 14 may be provided in the form of other devices in the electronic device 10 other than the display device 100. For example, the display module 11 may include the sub-pixels SP illustrated in FIG. 1.

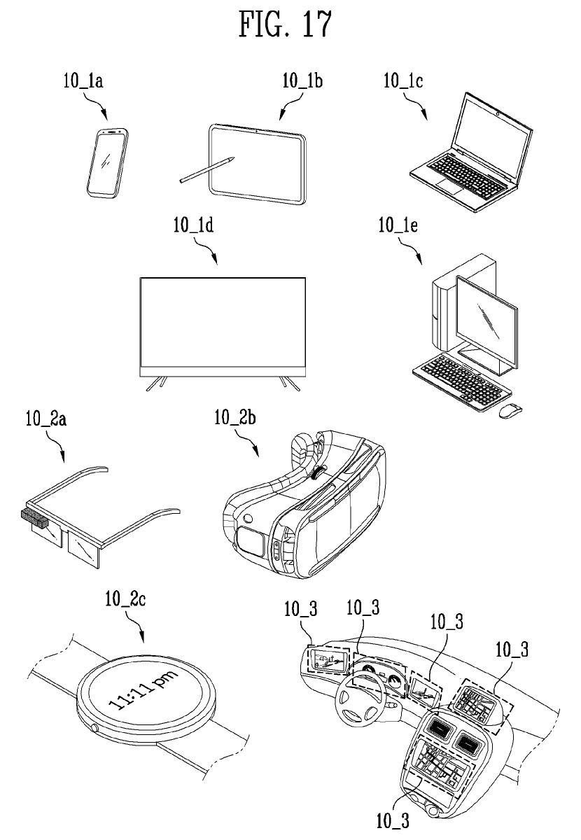

FIG. 17 illustrates schematic diagrams of an electronic device according to various embodiments.

Referring to FIG. 17, examples of various electronic devices to which the display device 100 according to embodiments of the present disclosure may include electronic devices for displaying images such as, for example, a smartphone 10_1a, a tablet PC 10_1b, a laptop 10_1c, a television 10_1d, or a desk monitor 10_1e, as well as wearable electronic devices including display modules such as, for example, smart glasses 10_2a, a head-mounted display 10_2b, or a smart watch 10_2c, and automotive electronic devices 10_3 including display modules such as, for example, an automotive dashboard, a center fascia, a Center Information Display (CID) placed on a dashboard, or a room mirror display.

The embodiments of the present disclosure have been described herein, but those skilled in the art will understand that various modifications and changes to the present disclosure can be made without departing from the spirit and scope of the present disclosure as set forth in the appended claims.

According to a sub-pixel, a display device including the sub-pixel, and an electronic device according to embodiments of the present disclosure, the amount of voltage change in a gate electrode of a driving transistor due to deterioration of a light emitting device may be minimized or reduced, and thus light with uniform luminance may be displayed. In some aspects, when the sub-pixel is initialized, a driving current is not supplied to an initialization voltage node, and thus power consumption may be reduced.

However, effects of the present disclosure are not limited to the above-described effects, and the effects may be variously extended without departing from the spirit and scope of the present disclosure.

What is claimed is:

1. A sub-pixel comprising:
a sub-pixel circuit connected to a first power voltage node to which a first power voltage is input, a data line, a first sub-gate line, and a first sub-emission control line;
a light emitting device having a cathode electrode connected to a second power voltage node to which a second power voltage is input; and
a first transistor connected between an anode electrode of the light emitting device and the sub-pixel circuit, wherein:
the first transistor turns off in response to a first voltage input to a second sub-emission control line to which a gate electrode of the first transistor is connected, and
the first transistor turns on in response to a second voltage input to the second sub-emission control line,
wherein a third voltage having a voltage value different from the first voltage and the second voltage is input to the second sub-emission control line during an emission period in which a driving current is supplied from the sub-pixel circuit to the light emitting device.

2. The sub-pixel according to claim 1, wherein the third voltage has a voltage value between the first voltage and the second voltage.

3. The sub-pixel according to claim 1, further comprising a second transistor connected between the anode electrode of the light emitting device and an initialization voltage node to which an initialization voltage is input, wherein the second transistor comprises a gate electrode connected to a second sub-gate line.

4. The sub-pixel according to claim 3, further comprising:
a third transistor having a first electrode connected to a first node, a second electrode connected to the first transistor, and a gate electrode connected to a second node;
a fourth transistor connected between the data line and the second node and having a gate electrode connected to the first sub-gate line;
a fifth transistor connected between the first power voltage node and the first node and having a gate electrode connected to the first sub-emission control line;
a first capacitor connected between the first node and the second node; and
a second capacitor connected between the first node and the first power voltage node.

5. The sub-pixel according to claim 4, wherein the first transistor, the second transistor, the third transistor, the fourth transistor, and the fifth transistor each comprise a body electrode to which the first power voltage is input.

6. The sub-pixel according to claim 4, wherein:
one horizontal period comprises a first period, a second period, and a third period, and
the first transistor is turned off during the first period, turned on during the second period and the third period, and turned on based on the third voltage during the emission period after the third period, wherein the first transistor has a predetermined resistance value based on the third voltage during the emission period.

7. The sub-pixel according to claim 6, wherein:
the second transistor is turned on during the first period to the third period,
the fourth transistor is turned on during the first period and the third period,
the fifth transistor is turned on during the first period and is turned off during the second period and the third period,
a reference voltage of a constant voltage is input to the data line during the first period, and
a data signal corresponding to a grayscale is input to the data line during the third period.

8. The sub-pixel according to claim 6, further comprising a sixth transistor connected between the second node and a reference voltage line to which a reference voltage is input, wherein the sixth transistor comprises a gate electrode connected to a third sub-gate line and a body electrode which receives the first power voltage.

9. The sub-pixel according to claim 8, wherein:
the second transistor is turned on during the first period to the third period,
the fourth transistor is turned on during the third period,
the fifth transistor is turned on during the first period, and is turned off during the second period and the third period,
the sixth transistor is turned on during the first period, and
a data signal corresponding to a grayscale is input to the data line during the third period.

10. A display device, comprising:
sub-pixels connected to data lines, gate lines, and emission control lines;
a gate driver which drives the gate lines and the emission control lines; and
a data driver which drives the data lines,
wherein:
at least one of the sub-pixels comprises:
a sub-pixel circuit connected to a first power voltage node to which a first power voltage is input, a data line which is one of the data lines, a first sub-gate line which is one of the gate lines, and a first sub-emission control line which is one of the emission control lines;
a light emitting device having a cathode electrode connected to a second power voltage node to which a second power voltage is input; and
a first transistor connected between an anode electrode of the light emitting device and the sub-pixel circuit and having a gate electrode connected to a second sub-emission control line which is one of the emission control lines, and
the gate driver supplies:
a first voltage to the second sub-emission control line, wherein the first transistor turns off in response to the first voltage;
a second voltage to the second sub-emission control line, wherein the first transistor turns on in response to the second voltage; and
a third voltage having a voltage value different from the first voltage and the second voltage to the second sub-emission control line during an emission period in which a driving current is supplied from the sub-pixel to the light emitting device.

11. The display device according to claim 10, wherein the third voltage has a voltage value between the first voltage and the second voltage.

12. The display device according to claim 10, wherein:
the sub-pixel further comprises a second transistor connected between the anode electrode of the light emitting device and an initialization voltage node to which an initialization voltage is input,
the second transistor comprises a gate electrode connected to a second sub-gate line which is one of the gate lines, and
the sub-pixel circuit comprises:
a third transistor having a first electrode connected to a first node, a second electrode connected to the first transistor, and a gate electrode connected to a second node;
a fourth transistor connected between the data line and the second node and having a gate electrode connected to the first sub-gate line;
a fifth transistor connected between the first power voltage node and the first node and having a gate electrode connected to the first sub-emission control line;
a first capacitor connected between the first node and the second node; and
a second capacitor connected between the first node and the first power voltage node.

13. The display device according to claim 12, wherein the gate driver supplies:
a disable second emission control signal of the first voltage to the second sub-emission control line during a first period;
an enable second emission control signal of the second voltage to the second sub-emission control line during a second period and a third period; and
a partial enable second emission control signal of the third voltage to the second sub-emission control line during the emission period after the third period.

14. The display device according to claim 13, wherein the first period, the second period, and the third period are comprised in one horizontal period.

15. The display device according to claim 13, wherein the gate driver supplies:
an enable first scan signal to the first sub-gate line such that the fourth transistor is turned on during the first period and the third period;
an enable first emission control signal to the first sub-emission control line such that the fifth transistor is turned on during the first period,
a disable first emission control signal to the first sub-emission control line such that the fifth transistor is turned off during the second period and the third period; and
an enable second scan signal to the second sub-gate line such that the second transistor is turned on during the first period to the third period.

16. The display device according to claim 15, wherein the data driver supplies:
a reference voltage of a constant voltage during the first period; and
a data signal corresponding to a grayscale during the third period.

17. The display device according to claim 15, wherein the gate driver simultaneously supplies the enable first scan signal to a plurality of first sub-gate lines located on a plurality of horizontal lines during the first period, and
wherein one horizontal period comprises the second period and the third period.

18. The display device according to claim 13, wherein the sub-pixel circuit further comprises a sixth transistor connected between the second node and a reference voltage line to which a reference voltage is input, and the sixth transistor comprises a gate electrode connected to a third sub-gate line which is one of the gate lines, and
wherein the gate driver supplies:
an enable first scan signal to the first sub-gate line such that the fourth transistor is turned on during the third period;
an enable first emission control signal to the first sub-emission control line such that the fifth transistor is turned on during the first period,
a disable first emission control signal to the first sub-emission control line such that the fifth transistor is turned off during the second period and the third period;
an enable second scan signal to the second sub-gate line such that the second transistor is turned on during the first period to the third period; and
an enable third scan signal to the third sub-gate line such that the sixth transistor is turned on during the first period.

19. The display device according to claim 18, wherein the third sub-gate line is connected in common to the sub-pixels.

20. An electronic device, comprising:
a processor;
a display module which displays an image according to an image data signal input from the processor;
memory which stores data information for an operation of the processor; and
a power module which generates power which drives the display module,
wherein:
the display module comprises:
sub-pixels connected to data lines, gate lines, and emission control lines;
a gate driver which drives the gate lines and the emission control lines; and
a data driver which drives the data lines,
at least one of the sub-pixels comprises:
a sub-pixel circuit connected to a first power voltage node to which a first power voltage is input, a data line which is one of the data lines, a first sub-gate line which is one of the gate lines, and a first sub-emission control line which is one of the emission control lines;
a light emitting device having a cathode electrode connected to a second power voltage node to which a second power voltage is input; and
a first transistor connected between an anode electrode of the light emitting device and the sub-pixel circuit, and having a gate electrode connected to a second sub-emission control line which is one of the emission control lines, and
the gate driver supplies:
a first voltage to the second sub-emission control line, wherein the first transistor turns off in response to the first voltage;
a second voltage to the second sub-emission control line, wherein the first transistor turns on in response to the second voltage; and
a third voltage having a voltage value different from the first voltage and the second voltage to the second sub-emission control line during an emission period in which a driving current is supplied from the sub-pixel to the light emitting device.
